(19) United States
(12) Patent Application Publication
(10) Pub. No.: US 2024/0319258 A1
(43) Pub. Date: Sep. 26, 2024

(54) METHOD FOR CALCULATING THE REMAINING CYCLIC LIFETIME OF AN ELECTRIC CONVERTER AND ELECTRIC CONVERTER FOR EXECUTING THE METHOD

(71) Applicant: Vacon Oy, Vaasa (FI)

(72) Inventors: Tuomas Yli-Rahnasto, Vaasa (FI); Ari Ristimäki, Laihia (FI); Matti Takala, Vaasa (FI); Juha Norrena, Mustasaari (FI)

(21) Appl. No.: 18/605,126

(22) Filed: Mar. 14, 2024

(30) Foreign Application Priority Data
Mar. 17, 2023 (DE) 102023106805.9

(51) Int. Cl. G01R 31/26

(52) U.S. Cl. CPC G01R 31/2642

(57) ABSTRACT

A method for calculating the remaining cyclic lifetime of an electric converter, such as an electric motor drive. The converter includes at least one power electronic module with at least one IGBT and diode, with or without a baseplate, a heatsink and at least one controller. The method includes the steps of repeatedly measuring the temperature of the reference point of the power electronic module; repeatedly measuring the operation conditions of the electronic module and calculating the power loss of the electronic module; repeatedly calculating the case temperature at the baseplate or the heatsink temperature at the heatsink based on the measured temperatures of the electronic module reference point, the power losses of the electronic module and the thermal impedance between electronic module reference point and case or thermal impedance between electronic module reference point and heatsink; repeatedly calculating the junction temperature based on the temperatures of the electronic module case temperature or on the heatsink temperature, the power losses of the electronic module IGBT and diode and the thermal impedance between junction and case or thermal impedance between junction and heatsink; storing the case and junction temperatures to memory; applying a rainflow cycle counting algorithm to the stored temperatures; calculating the remaining cyclic lifetime based on cyclic lifetime models of chip and baseplate; and outputting a signal indicative of the remaining cyclic lifetime. The disclosure further discloses an electric converter for executing the method.

### CROSS-REFERENCE TO RELATED APPLICATION

This application claims foreign priority benefits under 35 U.S.C. § 119 from German Patent Application No. 102023106805.9, filed Mar. 17, 2023, the content of which is hereby incorporated by reference in its entirety.

### TECHNICAL FIELD

The present invention is directed at a method for calculating the remaining cyclic lifetime of an electric converter, such as an electric motor drive. The converter comprises at least one power electronic module with at least one IGBT and diode, with or without a baseplate, a heatsink and at least one controller.

The invention is also directed at an electric converter for executing the method.

### BACKGROUND

The invention applies to drive applications with highly fluctuating loads. In such applications, the power electronic module components such as semiconductor chips may experience significant wear and associated aging. This eventually may lead to failure of the drive and a stop of a corresponding industrial process indirectly controlled by the drive. A significant factor for the aging is the case and chip temperature swing occurring during the fluctuating load conditions. The temperature swing and in particular the different thermal expansion coefficients of the semiconductor module components degenerate material layers of the semiconductor module and therefore reduce its cyclic lifetime.

The cyclic lifetime of a drive is usually a significant requirement, when selecting a drive for a certain user application. To estimate power electronic module lifetime, accurate operating conditions are needed. However, these accurate operating conditions are usually not easy to obtain or evaluate. Another problem encountered with prior art solutions is that the wearing process of a chip or other components may be difficult to observe by any measurements. The failure of the chip or other component due to end of cyclic lifetime therefore usually occurs without any warnings.

### SUMMARY

The aim of the present invention is to provide an improved method and electric converter, which overcome the above outlined problems. This aim is achieved by a method according to claim 1 and an electric converter according to claim 9. Preferable embodiments of the invention are subject to the dependent claims.

According to claim 1, a method for calculating the remaining cyclic lifetime of an electric converter is provided. The drive comprises at least one power electronic module with at least one IGBT and diode, with or without a baseplate, a heatsink and at least one controller. The method comprises the steps of
repeatedly measuring the temperature of the reference point of the power electronic module;
repeatedly measuring the operation conditions of the electronic module and calculating the power loss of the electronic module;
repeatedly calculating the case temperature at the baseplate or the heatsink temperature at the heatsink based on the measured temperatures of the electronic module reference point, the power losses of the electronic module and the thermal impedance between electronic module reference point and case or thermal impedance between electronic module reference point and heatsink;
repeatedly calculating the junction temperatures based on the temperatures of the electronic module case temperature or on the heatsink temperature, the power losses of the electronic module IGBT and diode and the thermal impedance between junction and case or thermal impedance between junction and heatsink;
storing the case and junction temperatures to memory;
applying a rainflow cycle counting algorithm to the stored temperatures;
calculating the remaining cyclic lifetime based on lifetime models of chip and baseplate; and
outputting a signal indicative of the remaining cyclic lifetime.

The basic idea of the present invention is to calculate online an estimation value of the thermal stress of an electronic component such as a power semiconductor module baseplate and a semiconductor chip or any other component during the drive operation. The thermal stress may apply to mechanical stresses present between two or more materials or components of different thermal expansion coefficients. The estimated thermal stress is output to a lifetime models of the module components such as the baseplate and chips.

The junction temperature may refer to a temperature assigned to an area inside a corresponding semiconductor device, where a virtual heat source provides thermal output originating from electrical power losses. The junction temperature may be regarded as a virtual parameter, which cannot be measured directly. It may constitute a theoretical average value from which the actual temperature at a chip pn-junction can differ significantly. This effect may increase linearly as a function of chip size.

The present invention improves predictive maintenance capabilities of the drive such that a user is able to read used lifetime consumption of the electronic module or other components of the electronic module or the drive in general. Additionally or alternatively, an alarm may be output whenever the drive requires service or maintenance activities due to aging components. This allows a user of the drive to schedule corresponding preventive activities better. Accordingly, the risk of a drive failure is reduced substantially. Furthermore, lifetime monitoring according to the present invention provides valuable information for root cause analysis of failed units with malfunctioning components such as semiconductor chips.

The actual power loss of the electronic module or other component is calculated in the drive by using information of operating conditions like output current, DC-link voltage, switching frequency etc. To calculate case and junction temperatures, thermal impedances between the measured reference point and the case and case to junction must be known. Case and junction temperatures are then calculated as thermal impedance multiplied by power loss with an added reference point temperature. The case and junction temperature data may be stored to memory. The rainflow cycle counting algorithm is applied to extract the stored temperature data and corresponding received temperature cycles. A lifetime model may be based on module baseplate and junction failure mechanisms and it may be calibrated with experimentally determined parameters from power cycling tests. Information indicative of the cycle lifetime may then be output to a user in several ways. For example, the user may read remaining lifetime of the drive as a percent value. Additionally or alternatively, a warning may be output in case a threshold value of remaining lifetime has been reached.

The invention provides a software function, which calculates the remaining cyclic lifetime of semiconductor module baseplate solder and chip solder/bonding in real time and generates a corresponding output in order to e.g. inform a user of the drive or a customer.

The invention provides added value to a user in that the user is better informed as to when to perform maintenance activities of the drive. The risk of unexpected process stops due to failed semiconductor modules and corresponding drive malfunctions is reduced. At the same time, the invention does not incur additional hardware costs for the drive. The invention provides clearly and easily measurable data indicative of the lifetime consumptions of the electronic components of the drive. Furthermore, the invention makes it possible to provide data on the field conditions of the drive.

In a preferred embodiment of the invention, the thermal impedances between the reference point to case or reference point to heatsink and case to junction or heatsink to junction of the power electronic module are established prior to the execution of the method and stored, preferably in the controller.

In another preferred embodiment of the invention, the temperature of the electronic module reference point is measured by means of a dedicated temperature sensor, such as an NTC-sensor.

In another preferred embodiment of the invention, the electronic module comprises a transistor and/or diode and/or thyristor.

In another preferred embodiment of the invention, the output signal corresponds to the remaining lifetime of the electric converter and/or the output signal corresponds to a warning signal.

In another preferred embodiment of the invention, the power loss of the electronic module is the sum of the power loss of the IGBT and the power loss of the diode.

In another preferred embodiment of the invention, the case temperature is calculated from the equation

$${T}_{C} ( t ) = {T}_{ref} ( t ) + ( {P}_{IGBT} ( t ) + {P}_{diode} ( t ) ) \times {Z}_{ref - C} ( t )$$

In another preferred embodiment of the invention, the junction temperature is calculated for the IGBT from the equation

$${T}_{j \_ IGBT} ( t ) = {T}_{C} ( t ) + {P}_{IGBT} ( t ) \times {Z}_{IGBT \_ j - C} ( t ) ,$$

and for the diode from the equation

$${T}_{j \_ diode} ( t ) = {T}_{C} ( t ) + {P}_{diode} ( t ) \times {Z}_{diode \_ j - C} ( t ) .$$

The invention is also directed at an electric converter comprising at least one power electronic module with or without a baseplate and at least one controller. The controller is provided for executing the method according to any of claims 1 to 8. The term controller is understood in a broad sense and may comprise any components required for performing its controlling tasks. Its components may comprise memory devices, computing devices, power devices etc.

### BRIEF DESCRIPTION OF THE DRAWINGS

Further details and advantages of the invention are described with respect to the figures. The figures show:

FIGS. 1a and 1b: schematic overview of an power electronic module with and without baseplate;

FIGS. 2a, 2b, 2c, and 2d: top side view and cross sectional view of the electronic module with (a and b) and without (c and d) baseplate;

FIG. 3: foster RC-network model of example thermal system;

FIG. 4: flow chart of electric power module lifetime prediction;

FIG. 5: junction temperature definition;

FIG. 6: graph illustrating the temperature calculation methods;

FIGS. 7a and 7b: temperature vs. time graphs of the electronic module;

FIG. 8a: graph illustrating the Tj cycle lifetime curve;

FIG. 8b: graph illustrating the test current flow of ΔTj power cycle and temperature change;

FIG. 9a: graph illustrating the TC cycle lifetime curve;

FIG. 9b: graph illustrating the test current flow of ΔTC power cycle and temperature change;

FIGS. 10a and 10b: rainflow cycle illustration; and

FIG. 11: flow chart of the presently described method.

### DETAILED DESCRIPTION

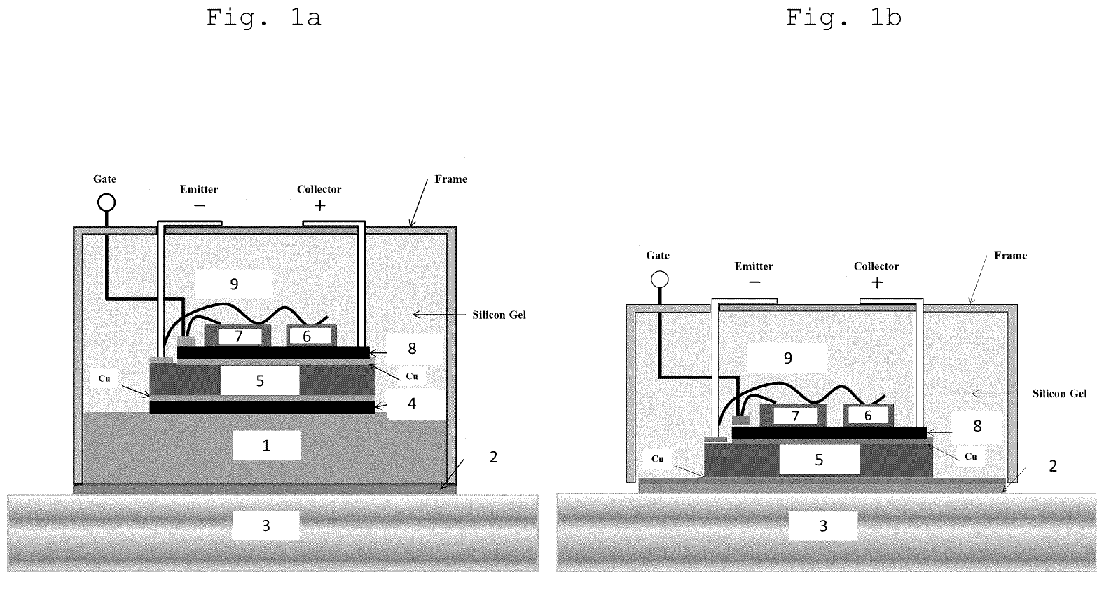

FIG. 1a shows a schematic overview of a power electronic module with baseplate 1 of an electric converter, such as a motor drive. The presently described method aims at calculating the cyclic lifetime of the electronic module and/or some of its components.

The electronic module may comprise the baseplate 1, which is connected via thermal interface material 2 to a heatsink 3 on one side and via a base plate solder 4 to the substrate 5 of the electronic module. Diodes 6 and IGBTs 7 may be connected to the substrate 5 via chip solders 8. Components such as the diodes 6 and IGBTs 7 may also be connected to the substrate 5 via bond wires 9. FIG. 1b shows an embodiment of the power electronic module structure without baseplate 1. Here, baseplate solder is not needed. Baseplate solder is usually the weakest point of the module case.

When the junction temperature Tⱼ of e.g. IGBT 7 or diode 6 chips and copper baseplate hot spot temperature T_{C} is increased and decreased, the largest mechanical stresses occur in the soldered joint between the insulated substrate DCB and the baseplate 1 or the bond wires 9 and baseplate solders 4 or chip solders 8, respectively. This cyclic thermal stress and in particular the difference in thermal expansion coefficient between the components may cause bond wire breaks, lift off, chip solder delamination and base plate solder delamination.

Solder delamination increases thermal resistance. Bond failure increases electrical resistance and moreover stresses intact bond wires more which leads to contact failures quickly.

Bond wire failures and chip solder delamination are typical failure modes in drive applications where cycle times are short and power is relatively high. Temperature swing of the junction Tⱼ is high. Baseplate solder delamination is typical failure mode in application where cycle times are long, usually a minute or more and power loss is relatively low. In this case, the whole module structure heats up and case temperature T_{C} swing is high.

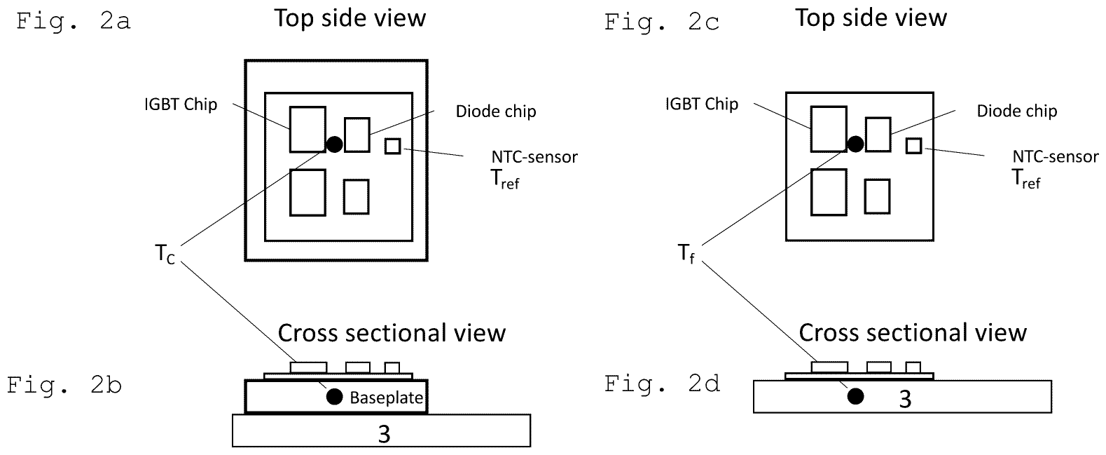

FIGS. 2a and 2b show a top side view and cross sectional view of the electronic module with baseplate 1 on a heatsink 3. The method may only measure NTC-sensor temperature T_{ref} of the electronic module. The NTC-sensor temperature T_{ref} may be different from the baseplate hot spot temperature T_{C} defined in cycle lifetime curves of the electronic components of the drive. Similarly, module construction without baseplate is shown in FIGS. 2c and 2d. T_{f} the hot spot heatsink temperature underneath the hottest chips.

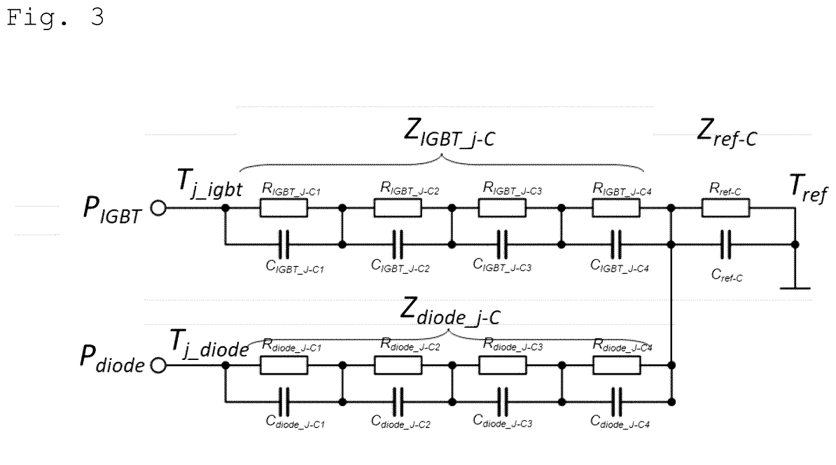

Dynamic thermal behaviour of the system can be modelled with RC-networks known as foster-models, such as the example shown in FIG. 3. Model parameters are dependent on configuration of the power electronic module. Thermal impedance between junction and case Z_{j-c} and case to NTC-sensor Z_{ref-C} is defined as thermal resistance and capacitance chains. Power loss P_{IGBT} and P_{diode} are input for the circuit. Junction and case temperatures can be calculated by solving the circuit equations.

The case temperature T_{C} may be calculated from the following equation

$${T}_{C} ( t ) = {T}_{ref} ( t ) + ( {P}_{IGBT} ( t ) + {P}_{diode} ( t ) ) \times {Z}_{ref - C} ( t ) .$$

Junction temperature Tⱼ may be calculated for IGBT from the following equation

$${T}_{j \_ IGBT} ( t ) = {T}_{C} ( t ) + {P}_{IGBT} ( t ) \times {Z}_{IGBT \_ j - C} ( t ) ,$$

and for a diode from the equation

$${T}_{j \_ diode} ( t ) = {T}_{C} ( t ) + {P}_{diode} ( t ) \times {Z}_{diode \_ j - C} ( t ) .$$

The thermal impedances may be defined experimentally. The location for determining the case temperature T_{C} may be at the bottom or upper side of the base plate and directly underneath the hottest component e.g. the hottest chip of the electronic module. If there is no baseplate 1 in the module, case temperature T_{C} can be replaced with heatsink temperature T_{f}. Then also thermal impedances may be defined from reference point to heatsink Z_{ref-f} and junction to heatsink Z_{j-f}.

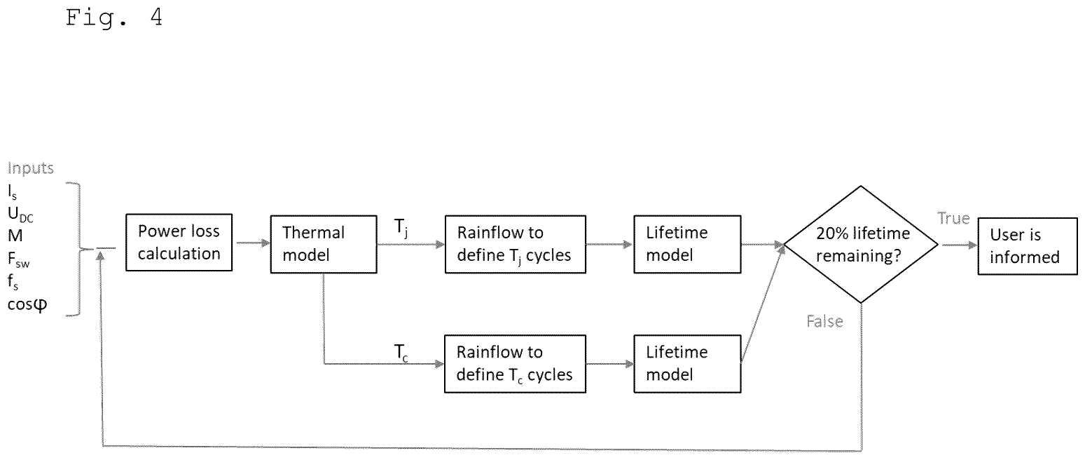

FIG. 4 shows a flow chart of the present invention's electric module lifetime prediction with Tⱼ-and T_{C}-calculation. T_{C} lifetime part can be neglected if considering baseplateless module construction.

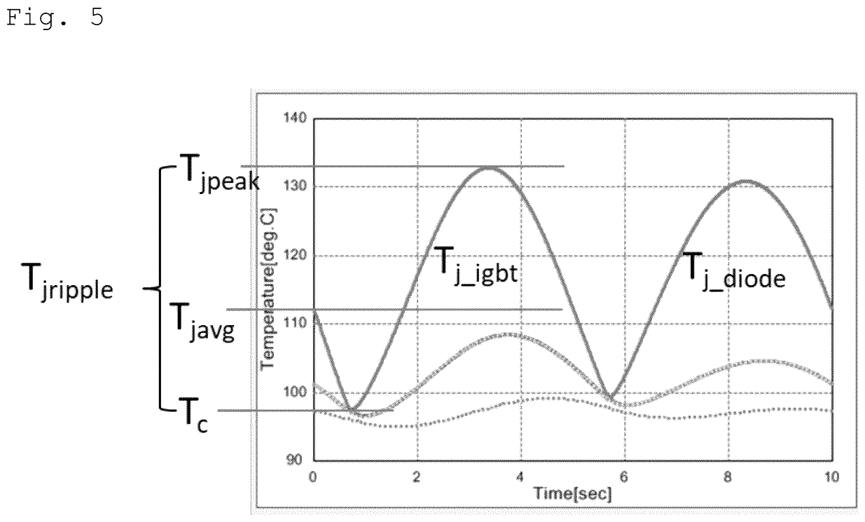

FIG. 5 provides a definition of the junction temperature Tⱼ.

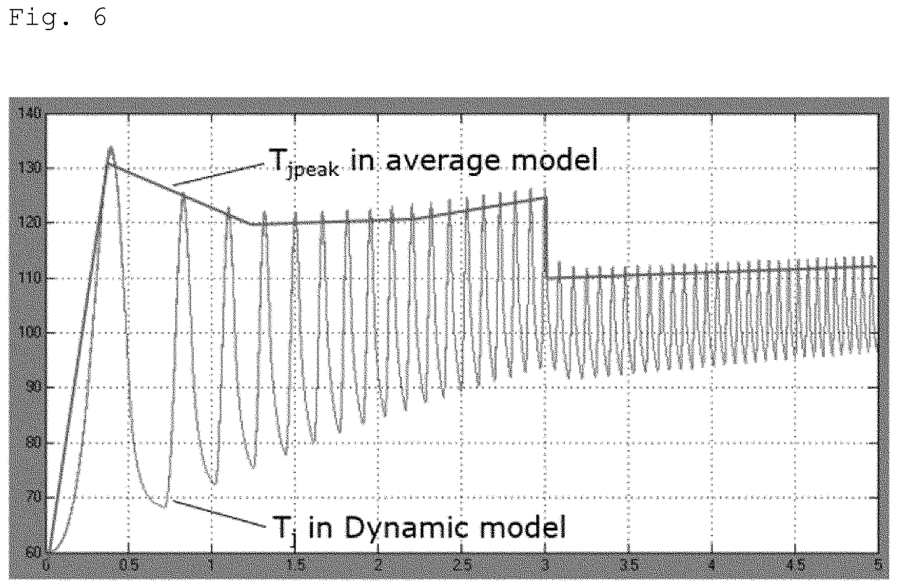

According to FIG. 6, two methods may be used for calculating the junction temperature Tⱼ. The average method has lower computational requirements. It calculates the average junction losses and peak temperature Tⱼₚₑₐₖ. According to the dynamic method, loss and temperature calculations are based on instantaneous measurements. However, in the average method output frequency temperature ripple Tⱼᵣᵢₚₚₗₑ can be estimated quite accurately by peak temperature Tⱼₚₑₐₖ and average temperature T_{javg}.

The output frequency temperature ripple may be calculated from the following equation:

$${T}_{jripple} = ( {T}_{jpeak} - {T}_{javg} ) + ( {T}_{javg} - {T}_{c} )$$

Here, Tⱼₚₑₐₖ of FIGS. 5 and 6 corresponds to Tⱼ mentioned throughout other parts of the description.

The cycle length Tₒₙ is calculated from the following equation:

$${T}_{on} = 1 / ( 2 * {f}_{out} )$$

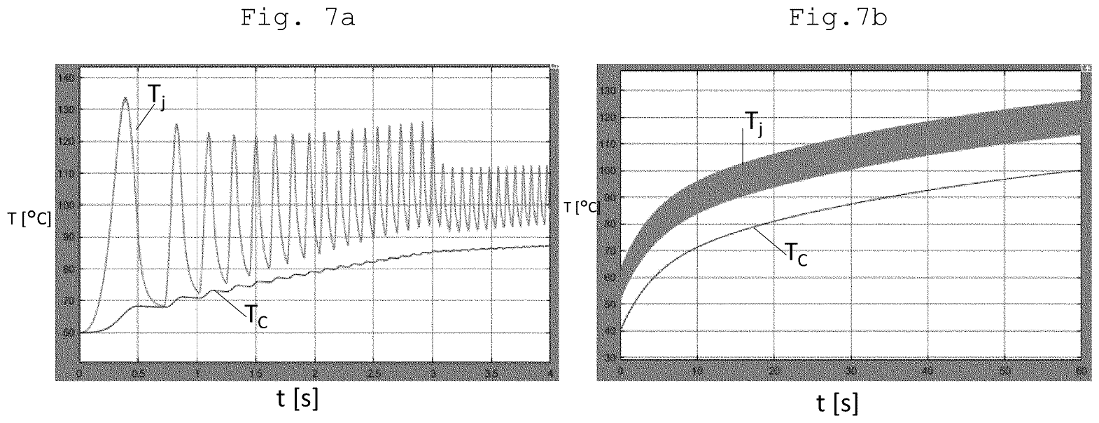

FIGS. 7a and 7b show temperature vs. time graphs of the electronic module. They provide some background on the characteristics of the drive's power module with respect to its lifetime. The lifetime of the IGBT power module of the drive is highly dependent on its application and driving conditions. The IGBT has two main failure mechanisms: The first one is chip solder/bonding failure and the second one is DCB to baseplate solder failure. In both cases, variation of temperature is the reason for lifetime reduction.

In the presently described example of a motor drive, a motor high current and low frequency acceleration or start ramp may stress the chip solder and bonding as shown in FIG. 7a. During a one-minute high overload cycle as shown in FIG. 7b, the whole cooling system heats up and stresses mostly the DCB to baseplate solder layer. This is the reason why both failure mechanisms needs to be monitored separately.

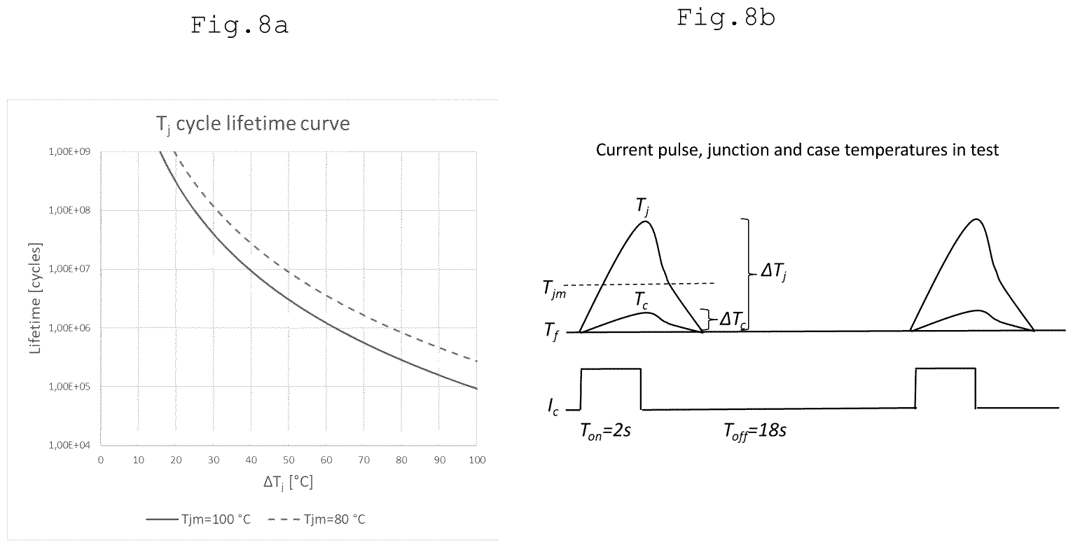

FIG. 8a shows a graph illustrating the Tⱼ cycle lifetime curves for two different mean temperatures, Tⱼₘ at 100° C. and Tⱼₘ at 80° C. FIG. 8b shows a graph illustrating the current flow of ΔTⱼ power cycle and temperature change with two mean temperatures Tⱼₘ.

Usually, power modules have defined cyclic lifetimes as a function of temperature swings. FIG. 8a shows an exemplary lifetime curve. The curve is based on DC-current cycling test shown in FIG. 8b. The end of lifetime criteria may be a 20% increase in thermal resistance from an initial value between the junction and the baseplate. The presently described invention may use an F(t)=10% curve of the accumulated failure rate of the corresponding Weibul analysis chart.

The Lesit model makes it possible to take mean temperature Tⱼₘ and pulse length T_{on(application)} into account. Here, the following equation applies:

$${N}_{test} = A \cdot Δ {T}_{j}^{α} \cdot {e}^{( \frac{{E}_{a}}{{k}_{b} \cdot {T}_{jm}} )}$$

In order to take cycle duration into account, the following equation may be used:

$${N}_{toncor} = {N}_{test} \cdot {( \frac{{t}_{on ( application )}}{{t}_{on ( test )}} )}^{{k}_{toncor}}$$

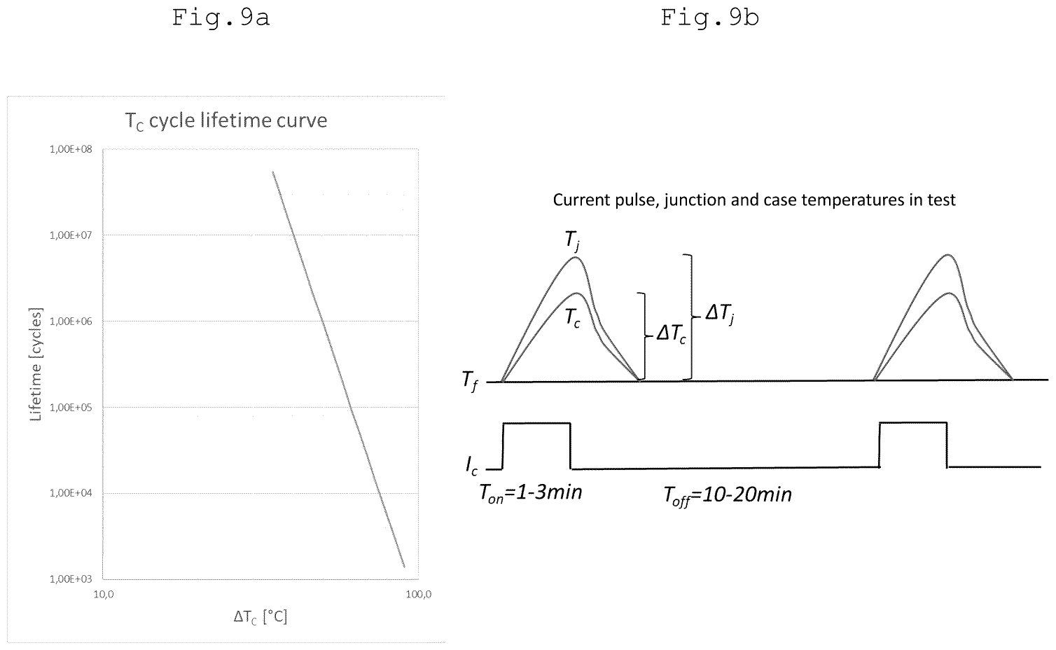

FIG. 9a shows a graph illustrating the T_{C} cycle lifetime curve. It shows amounts of cycles the baseplate solder withstands with certain ΔT_{C}. This step can be neglected in case of electronic modules without baseplate. FIG. 9b shows a graph illustrating the current flow of ΔT_{C} power cycle and temperature change in the test.

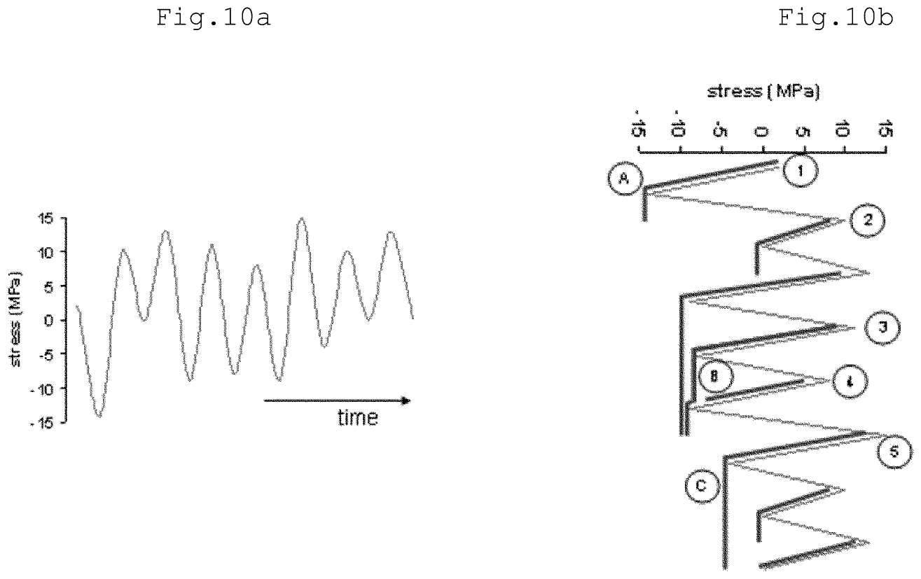

FIGS. 10a and 10b illustrate the rainflow cycle model. A summary of the rainflow cycle as provided in “Rainflow-counting algorithm”, Wikipedia, Wikimedia Foundation, 23 Nov. 2021, https://en.wikipedia.org/wiki/Rain flow-counting_algorithm reads as follows:
1. Reduce the time history to a sequence of (tensile) peaks and (compressive) valleys.
2. Imagine that the time history is a template for a rigid sheet (pagoda roof).
3. Turn the sheet clockwise 90° (earliest time to the top).
4. Each “tensile peak” is imagined as a source of water that “drips” down the pagoda.
5. Count the number of half-cycles by looking for terminations in the flow occurring when either:
   It reaches the end of the time history;
   It merges with a flow that started at an earlier tensile peak; or
   It flows when an opposite tensile peak has greater magnitude.
6. Repeat step 5 for compressive valleys.
7. Assign a magnitude to each half-cycle equal to the stress difference between its start and termination.
8. Pair up half-cycles of identical magnitude (but opposite sense) to count the number of complete cycles. Typically, there are some residual half-cycles.

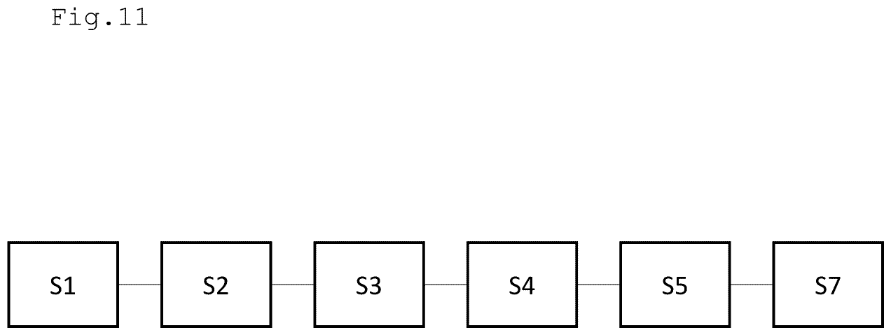

FIG. 11 is a flow chart of the inventive method. The method comprises the following steps:
S1: repeatedly measuring the temperature of the electronic module T_{ref},
S2: repeatedly measuring operation conditions and calculating the power loss of the electronic module P_{EM};
S3: repeatedly calculating the case temperature T_{C} or heatsink temperature T_{f} and junction temperatures Tⱼ based on the temperatures of the electronic module T_{ref}, the power losses of the electronic module P_{EM} and the thermal impedances of the system;
S4: storing the case temperatures Tc and junction temperatures Tⱼ to memory;
S5: applying a rainflow cycle counting algorithm to the stored temperatures T_{C} and Tⱼ;
S6. calculating remaining cyclic lifetime based on the lifetime models; and
S7: outputting a signal indicative of remaining cyclic lifetime.

In a preferred embodiment of the invention, the thermal impedances Z_{ref-C}, Z_{ref-f}, Z_{j-C} and Z_{j-f} between the reference point to case or reference point to heatsink 3, case to junction or heatsink to junction of the power electronic module are established prior to the execution of the method and stored, preferably in the controller.

In another preferred embodiment of the invention, the temperature of the electronic module is measured by means of a dedicated temperature sensor, such as an NTC-sensor.

In another preferred embodiment of the invention, the electronic module comprises a transistor and/or diode and/or thyristor.

In another preferred embodiment of the invention, the output signal corresponds to the remaining lifetime of the motor drive and/or that the output signal corresponds to a warning signal.

In another preferred embodiment of the invention, the power loss of the electronic module PEM is the sum of the power loss of the IGBT and the power loss of the diode P_{diode}.

In another preferred embodiment of the invention, the case temperature T_{C} is calculated from the equation

$${T}_{C} ( t ) = {T}_{ref} + ( {P}_{IGBT} ( t ) + {P}_{diode} ( t ) ) \times {Z}_{ref - C} ( t ) .$$

In another preferred embodiment of the invention, the junction temperature Tⱼ for the IGBT is calculated from the equation

$${T}_{j \_ IGBT} ( t ) = {T}_{C} ( t ) + {P}_{IGBT} ( t ) \times {Z}_{IGBT \_ j - C} ( t ) ,$$

and for the diode from the equation

$${T}_{j \_ diode} ( t ) = {T}_{C} ( t ) + {P}_{diode} ( t ) \times {Z}_{diode \_ j - C} ( t )$$

The invention is also directed at an electric converter, such as a motor drive, comprising at least one power electronic module with or without a case and at least one controller. The controller is provided for executing the presently described method. The term controller is understood in a broad sense and may comprise any components required for performing its controlling tasks. Its components may comprise memory devices, computing devices, power devices.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A method for calculating the remaining cyclic lifetime of an electric converter comprising at least one power electronic module with at least one IGBT and diode, with or without a baseplate, a heatsink and at least one controller, the method comprising the steps of:
repeatedly measuring the temperature of the reference point of the power electronic module;
repeatedly measuring the operation conditions of the power electronic module and calculating the power loss of the power electronic module;
repeatedly calculating the case temperature at the baseplate or the heatsink temperature at the heatsink based on the measured temperatures of the electronic module reference point, the power losses of the electronic module and the thermal impedance between electronic module reference point and case or thermal impedance between electronic module reference point and heatsink;
repeatedly calculating the junction temperatures based on the temperatures of the electronic module case temperature or on the heatsink temperature, the power losses of the electronic module IGBT and diode and the thermal impedance between junction and case or thermal impedance between junction and heatsink;
storing the case temperature and junction temperature to memory;
applying a rainflow cycle counting algorithm to the stored temperatures;
calculating the remaining cyclic lifetime based on cyclic lifetime models of chip and baseplate; and
outputting a signal indicative of the remaining cyclic lifetime.

2. The method according to claim 1, wherein the thermal impedances between the reference point to case or reference point to heatsink and case to junction or heatsink to junction of the power electronic module are established prior to the execution of the method and stored, preferably in the controller.

3. The method according to claim 1, wherein the temperature of the electronic module reference point is measured by means of a dedicated temperature sensor, such as an NTC-sensor.

4. The method according to claim 1, wherein the electronic module comprises a transistor and/or diode and/or thyristor.

5. The method according to claim 1, wherein the output signal corresponds to the remaining lifetime of the electric converter and/or that the output signal corresponds to a warning signal.

6. The method according to claim 1, wherein the power loss of the electronic module is the sum of the power loss of the IGBT and the power loss of the diode.

7. The method according to claim 6, wherein the case temperature is calculated from the equation
$${T}_{C} ( t ) = {T}_{ref} ( t ) + ( {P}_{IGBT} ( t ) + {P}_{diode} ( t ) ) \times {Z}_{ref - C} ( t ) .$$

8. The method according to claim 4, wherein the junction temperature Tⱼ is calculated for the IGBT from equation
$${T}_{j \_ IGBT} ( t ) = {T}_{C} ( t ) + {P}_{IGBT} ( t ) \times {Z}_{IGBT \_ j - C} ( t ) ,$$
and for the diode from equation
$${T}_{j \_ diode} ( t ) = {T}_{C} ( t ) + {P}_{diode} ( t ) \times {Z}_{diode \_ j - C} ( t ) .$$

9. An electric converter comprising at least one power electronic module with or without a baseplate and at least one controller, wherein the controller is provided for executing the method according to claim 1.

10. The method according to claim 2, wherein the temperature of the electronic module reference point is measured by means of a dedicated temperature sensor, such as an NTC-sensor.

11. The method according to claim 2, wherein the electronic module comprises a transistor and/or diode and/or thyristor.

12. The method according to claim 3, wherein the electronic module comprises a transistor and/or diode and/or thyristor.

13. The method according to claim 2, wherein the output signal corresponds to the remaining lifetime of the electric converter and/or that the output signal corresponds to a warning signal.

14. The method according to claim 3, wherein the output signal corresponds to the remaining lifetime of the electric converter and/or that the output signal corresponds to a warning signal.

15. The method according to claim 4, wherein the output signal corresponds to the remaining lifetime of the electric converter and/or that the output signal corresponds to a warning signal.

16. The method according to claim 2, wherein the power loss of the electronic module is the sum of the power loss of the IGBT and the power loss of the diode.

17. The method according to claim 3, wherein the power loss of the electronic module is the sum of the power loss of the IGBT and the power loss of the diode.

18. The method according to claim 4, wherein the power loss of the electronic module is the sum of the power loss of the IGBT and the power loss of the diode.

19. The method according to claim 5, wherein the power loss of the electronic module is the sum of the power loss of the IGBT and the power loss of the diode.
